(19) United States
(12) Patent Application Publication
(10) Pub. No.: US 2005/0248028 A1
(43) Pub. Date: Nov. 10, 2005

(54) CHIP-PACKAGING WITH BONDING OPTIONS CONNECTED TO A PACKAGE SUBSTRATE

(76) Inventor: Cheng-Yen Huang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/709,428

(22) Filed: May 5, 2004

(51) Int. Cl. H01L 29/00

(52) U.S. Cl. 257/724

(57) ABSTRACT

An integrated circuit package includes a semiconductor chip, bonding pads on the semiconductor chip, a metal lead frame containing electrically with the semiconductor chip, a plurality of wired pins wire-bonded respectively to the bonding pads, and at least one non-wired pin. The non-wired pin is wire-bonded to the metal lead frame to prevent electrostatic discharge failure of the integrated circuit package due to electrostatic discharge stressing of the non-wired pin.

### BACKGROUND OF INVENTION

1. Field of the Invention

This invention relates to a chip-packaging, and more particularly to a chip-packaging with bonding options connected to a package substrate.

2. Description of the Prior Art

In modern VLSI circuit design, circuits in a package are connected to an outside power supply or other devices by a bonding mechanism. Therefore, allocations of bonding pads and methods of bonding options are basic and important technologies. In general, there are many different functions in one circuit, and there are many pins corresponding to the different functions in a circuit package. However, not all functions of the circuit are used, so some pins in the circuit package are connected to outside circuits while others do not. Thus, some pins called Enable and Disable are provided. Pins having the function of Enable mean that when the pins are given a fixed high voltage (usually the voltage of the power supply), some functions corresponding to these pins in the chip are enabled. Similarly, pins having the function of Disable mean that some functions of the chip are disabled when the pins are given a fixed low voltage (usually the GND voltage). The Enable pins and the Disable pins allow users to be able to choose the different functions of the chip so as to increase efficiency of the chip.

The method of providing a bonding option is used to provide Enable, Disable, and Input/Output options for some pins of a package. This method not only allows users to change the hardware configuration of VLSI circuits, but also to provide detecting and debugging of the VLSI circuits.

In the prior art, one bonding option usually comprises a plurality of bonding pads. These bonding pads provide different bonding choices. For example, a bonding pad can be connected to a high voltage pin (supply voltage) or a low voltage pin (ground). Previous architectures of the bonding options include two types: the value-default type and the power/ground proximity type. Please refer to FIG. 1 and FIG. 2. FIG. 1 and FIG. 2. illustrate an architecture of the bonding option of the value-default type. In the architecture, each bonding pad is connected to a logic “1” of a high voltage or a logic “0” of a low voltage in the bonding option circuitry. If there is not any input signal applied to the pin of the bonding pad, the voltage of the pin will maintain a default voltage, which depends on what the pin is connected to. For example, the default voltage is high voltage “1” in the bonding option of the value-default type of FIG. 1. If the voltage of the pin is not defined by an outside system, the pin has logic “1”. On the other hand, the default voltage is low voltage “0” in the bonding option of the value-default type of FIG. 2, and thus if the voltage of the pin is not defined by an outside system, the pin has logic “0”.

Here we further state the principle of operations in FIG.1 and FIG. 2. Please refer to FIG. 1. The bonding option device 12 of the value-default type in FIG. 1 comprises a passive circuit 10. The passive circuit 10 that is connected to POWER and the power supply consists of a PMOS. The passive circuit 10 has small resistance so that it has really high conductivity. When the passive circuit 10 turns on, the voltage drop between the drain and the source of the PMOS is almost zero. Therefore, POWER is set to the voltage of the power supply. In other words, when POWER is not input by outside signals, the passive circuit 10 turns on and POWER increases to a high voltage so that the inside circuitry will receive a signal of logic “1” from the bonding pad.

Please refer to FIG. 2. The bonding option device 16 of the value-default type FIG. 2 comprises a passive circuit 14. The passive circuit 10 that is connected to GND and the ground consists of a NMOS. The passive circuit 14 also has small resistance so that it has considerably high conductivity. When the passive circuit 14 turns on, the voltage drop between the drain and the source of the NMOS is almost zero. Therefore, GND is set to the voltage of the ground. Say, when GND is not applied by outside signals, the passive circuit 14 turns on and GND is forced to a low voltage so that the inside circuitry will receive a signal of logic “0” from the bonding pad.

However, the architecture has undesirable disadvantages. If one bonding pad of the architecture is applied by an input signal from an outside system and the input signal is different from the default voltage, it leads to additional power consumption. This disadvantage is serious in the modern electronic devices of small sizes.

Please refer to FIG. 3. FIG. 3 illustrates the well-known architecture 17 of the bonding option of the power/ground proximity type. The architecture comprises a plurality of bonding pads, and each bonding pad is adjacent to a POWER and a GND. These bonding pads do not have a default voltage. If one bonding pad must be connected to logic “1”, the bonding pad is connected to POWER in FIG. 3. If one bonding pad must be connected to logic “0”, the bonding pad is connected to GND. The architecture not only provides logic “1” or “0” for bonding pads but also avoids power waste. However, as described before, each bonding pad needs two connection points, POWER and GND for bonding choices, so these connection points and each bonding pad should be specially arranged. In the case of a chip with many pins, arrangement of the bonding pads becomes very troublesome.

### SUMMARY OF INVENTION

It is therefore an objective of the claimed invention to provide an effective bonding-option method in order to solve the above-mentioned problems.

According to the claimed invention, a chip-packaging with bonding options connected to a package substrate includes a package substrate, and a chip mounted on the package substrate, the chip comprising a plurality of bonding pads, one of the bonding pads being connected to the package substrate. The chip-packaging also includes a lead frame connected to one of the bonding pads.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 illustrates an architecture of the bonding option of the value-default type.

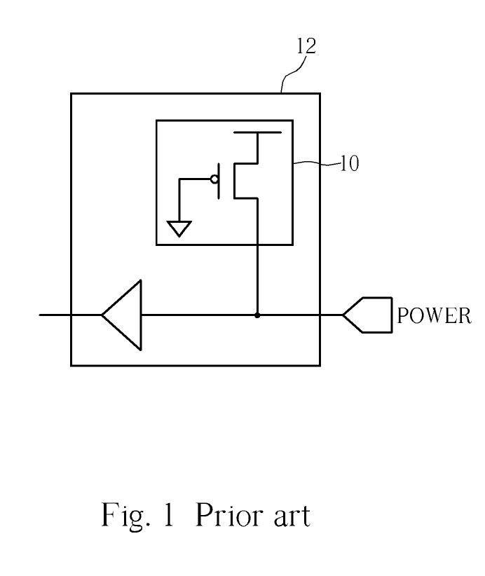

FIG. 2 illustrates an architecture of the bonding option of the value-default type.

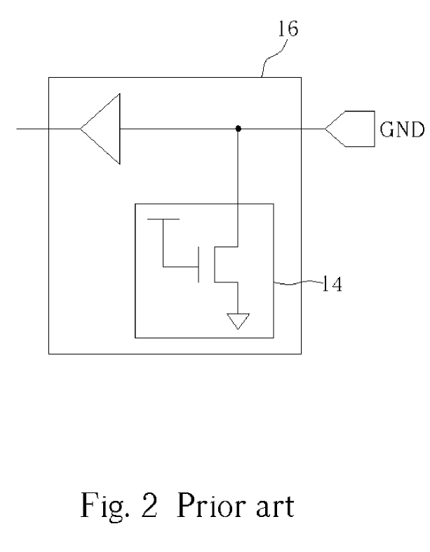

FIG.3 illustrates the well-known architecture of the bonding option of the power/ground proximity type.

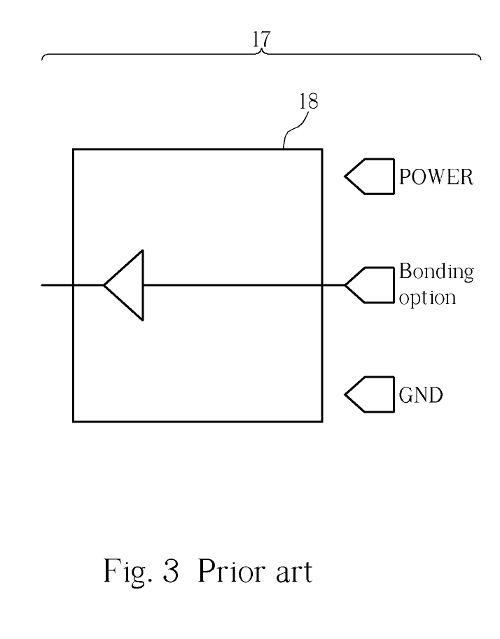

FIG.4 illustrates chip-packaging with bonding options according to the present invention.

FIG.5 illustrates functions of each element in FIG.4.

FIG.6 illustrates the architecture of the bonding options in the present invention.

### DETAILED DESCRIPTION

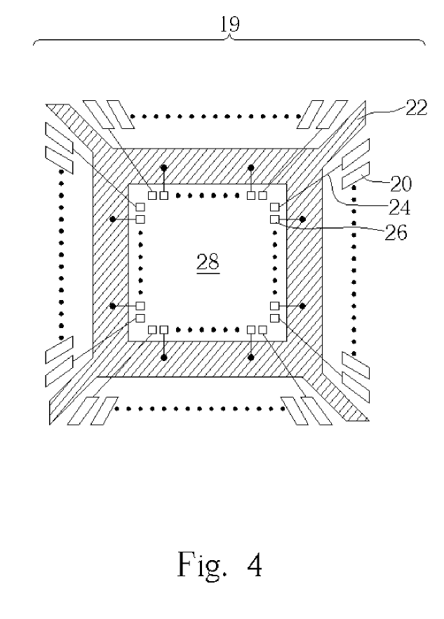

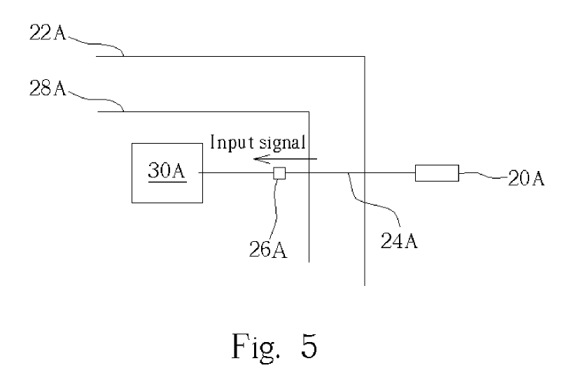

Please refer to FIG.4. FIG.4 illustrates chip-packaging 19 with bonding options according to the present invention. The chip-packaging 19 comprises a plurality of lead frames 20, a plurality of bonding wires 24, a chip 28, a package substrate 22, and a plurality of bonding pads 26. The chip 28 is mounted on the package substrate 22, and the bonding pads 26 are distributed on and around four sides of the chip 28 so that inputs/outputs of the chip 28 can be connected to the outside system. The lead frames 20 are distributed around the chip 28 and outside the chip 28. The bonding wires 24 connect the bonding pads 26 to the lead frames 20. The bonding pads 26 can be seen as the connection points from inside of the chip 28, while the lead frames 20 serve as the connection points for outside systems. The detailed description of the structure is referred to FIG.5. FIG.5 illustrates functions of each element in FIG. 4. The package of the FIG. 5 comprises a lead frame 20A, a bonding wire 24A, a chip 28A, a package substrate 22A, and a bonding pad 26A. The chip 28A further comprises a circuit 30A. The circuit 30A needs an input signal from the outside system for operation and the input signal enters the circuit 30A from the bonding pad 26A. As mentioned before, the bonding pad 26A is the connection point for the chip 28A to communicate with outside systems. Therefore, the bonding pad 26A is connected to the lead frame 20A through the bonding wire 24A, and the input signals from the outside systems are applied to the lead frame 20A and finally enter the circuit 30A. Thus, the outside signals enter the chip 28A. In summary, the bonding options of the present invention lets the inputs/outputs of a chip connect to the outside circuitry and provides testing of a chip.

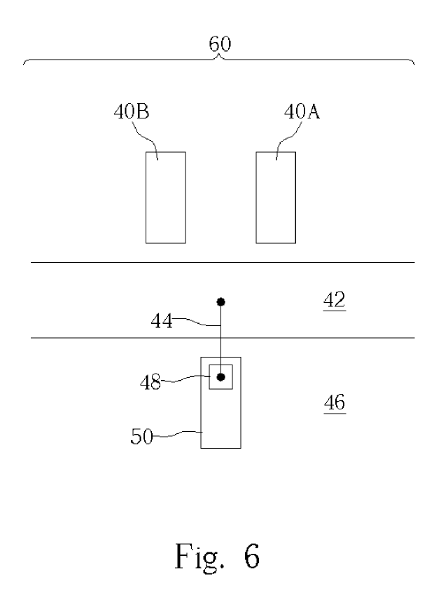

Please refer to FIG.6. FIG.6 illustrates the architecture 60 of the bonding options in the present invention. The architecture 60 of the bonding options comprises a first lead frame 40A, a second lead frame 40B, a package substrate 42, a bonding wire 44, a chip 46 and a bonding option unit 50. The architecture in FIG.6 is derived from that in FIG.5. Thus, the elements in FIG.6 with the same name as those in FIG.5 have the same functions. The bonding option unit 50 including the bonding pad 48 is connected to the inside circuit of the chip 46, allowing inputs/outputs of the chip 46 to be connected to outside systems through the bonding pad 48. As mentioned in the prior art, usually one bonding option unit of a chip has to connect to three possible connection points, which are ground, power supply and bonding option. Because one chip usually has different functions or configurations, some pins of the chip must be given their voltage, Enable or Disable, before the chip is packaged. Enable is usually represented by a high voltage of logic “1” (voltage of the power supply). When one pin of a chip is connected to a power supply, some function of the chip is enabled. In contrast, Disable is usually represented by a low voltage of logic “0” (voltage of the ground). When one pin of a chip is connected to ground, some function of the chip is disabled. Enable and Disable make it possible that one chip with many functions can be set to one of the functions according to different applications. Also, Enable and Disable representing logic “1” and logic “0” can be used for testing chips.

The bonding option unit 50 is possibly connected to Enable and Disable (power supply and ground). Besides, the bonding option unit 50 may be connected to the control signal of the outside systems. Thus, the signals of the outside system can input the chip 46 or the signals of the chip 46 outputs by the option unit 50. Therefore, (please refer to FIG. 6) three connection points are provide around a bonding pad 48, the lead frame 40A serving as the first bonding option, the lead frame 40B serving as the second bonding option, and the package substrate 42 serving as the third bonding option. The first bonding option is provided for outputting or inputting signals. The second bonding option and the third bonding option provide the voltage of the power supply or the voltage of the ground. In the embodiment of the present invention, the lead frame 40B serving as the second bonding option provides the voltage of the power supply. The package substrate 42 serving as the third bonding option provides the voltage of the ground. Of course, the lead frame 40B and the package substrate 42 can also exchange roles. Therefore, in this embodiment, when the bonding option unit 50 needs to connect to the power supply, the bonding wire 44 combines the bonding pad 48 and the lead frame 40B, and the power supply is input into the inside circuit of the chip 46 through the bonding option unit 50. When the bonding option unit 50 requires the voltage of the ground, the bonding wire 44 connects the bonding pad 48 and the package substrate 42 so that the bonding option unit 50 has the voltage of the ground. In the last situation, the bonding option unit 50 is connected to the lead frame 40A by the bonding wire 44, and provides transmission traces of input and output signals.

Notice that in FIG.6 there are two lead frames 40A and 40B set around the bonding option unit 50. Actually, two lead frames can implement the functions of the present invention. However, lead frames set for a bonding option unit 50 are not limited to two. In specific cases, the number of the lead frames can be more than three or can be only one. The method of applying a voltage to one package substrate and providing the voltage to a bonding pad by the package substrate is included in the present invention regardless of the number of lead frames.

In the bonding option of the value-default type of the prior art, if one bonding pad of the architecture is applied by an input signal from an outside system and the input signal is different from the default voltage, it leads to additional power consumption. It is an unacceptable disadvantage in the modern electronic technology of low power. On the other hand, the bonding option of the power/ground proximity type in the prior art, though, removes the problem of additional power consumption. In the case of a chip having many pins, arrangement of the bonding pads becomes a big problem because the connection points and each bonding pad should be specially arranged. Moreover, due to the large area of the boding pads, if the number of the bonding pads is large, the chip area will be unnecessarily increased using the bonding option of the power/ground proximity type, raising the production cost.

Compared to the prior art, the present invention utilizes package substrate as one voltage supply, such as the voltage of the power supply and the ground, to implement bonding option without increasing additional lead frames. Therefore, the present invention has the following advantages: 1. Provide convenient testing and other functions for a chip, and let a single chip operate in different modes. 2. Make it easier to arrange lead frames because only one lead frame is needed for providing the voltage of the power supply and the ground. 3. It is easier to use and maintain the bonding option. 4. Less number of lead frames leads to smaller layout area and lower production cost. The present invention not only offers the advantages of the prior art, but also provides additional advantages that the prior art cannot achieve.

Those skilled in the art will readily observe that numerous modifications and alterations of the device may be made while retaining the teachings of the invention. Accordingly, the above disclosure should be construed as limited only by the metes and bounds of the appended claims.

1-10. (canceled)

11. A chip-packaging with bonding options connected to a package substrate, comprising:
a package substrate;
a chip mounted on the package substrate, the chip comprising a plurality of bonding pads, a first bonding pad directly contacting the package substrate;
a first lead frame connected to a second bonding pad through a first pin of the chip; and
a second lead frame connected to a third bonding pad through a second pin of the chip for receiving input signals to control the voltage level of the second pin.

12-18. (canceled)

19. A method of packaging a chip having a bonding option connected to a package substrate, comprising:
providing the package substrate;
mounting the chip on the package substrate, the chip comprising a plurality of bonding pads;
connecting a first bonding pad directly to the package substrate;
connecting a second bonding pad to a first lead frame through a first pin of the chip;
connecting a third bonding pad to a second lead frame through a second pin of the chip; and
receiving input signals through the second lead frame for controlling the voltage level of the second pin.

20-26. (canceled)

27. A chip-packaging with bonding options connected to a package substrate, comprising:
a package substrate connected to either a high voltage or a low voltage;
a chip mounted on the package substrate, the chip comprising a plurality of bonding pads, a first bonding pad directly contacting the package substrate;
a first lead frame connected to a second bonding pad through a first pin of the chip, the first lead frame being connected to either a high voltage or a low voltage, and the voltage level of the first pin being the logical opposite of the voltage level of the package substrate; and
a second lead frame connected to a third bonding pad through a second pin of the chip for receiving input signals to control the voltage level of the second pin.

28. The chip-packaging of claim 27, wherein the high voltage is a power supply and the low voltage is ground.

29. The chip-packaging of claim 27, wherein the package substrate is connected to a power supply and the first lead frame is connected to ground.

30. A method of packaging a chip having a bonding option connected to a package substrate, comprising:
providing the package substrate connected to either a high voltage or a low voltage;
mounting the chip on the package substrate, the chip comprising a plurality of bonding pads;
connecting a first bonding pad directly to the package substrate;
connecting a second bonding pad to a first lead frame through a first pin of the chip, the first lead frame being connected to either a high voltage or a low voltage, and the voltage level of the first pin being the logical opposite of the voltage level of the package substrate;
connecting a third bonding pad to a second lead frame through a second pin of the chip; and
receiving input signals through the second lead frame for controlling the voltage level of the second pin.

31. The method of claim 30, wherein the high voltage is a power supply and the low voltage is ground.

32. The method of claim 30, wherein the package substrate is connected to a power supply and the first lead frame is connected to ground.
